(19) United States
(12) Patent Application Publication
(10) Pub. No.: US 2022/0238778 A1
(43) Pub. Date: Jul. 28, 2022

(54) TUBULAR HEAT EXCHANGER WITH THERMOELECTRIC POWER GENERATION FUNCTION AND ITS MANUFACTURING METHOD AND THERMOELECTRIC POWER GENERATION DEVICE USING THE SAME

(71) Applicants: E-ThermoGentek Co., Ltd., Kyoto-shi, Kyoto (JP); KAWASAKI JUKOGYO KABUSHIKI KAISHA, Kobe-shi, Hyogo (JP); KAWASAKI THERMAL ENGINEERING CO., LTD., Kusatsu-shi, Shiga (JP)

(72) Inventors: Michio OKAJIMA, Kyoto-shi, Kyoto (JP); Nao MAJIMA, Kyoto-shi, Kyoto (JP); Takashi UNO, Kyoto-shi, Kyoto (JP); Keiichi OHATA, Kyoto-shi, Kyoto (JP); Shutaro NAMBU, Kyoto-shi, Kyoto (JP); Makoto GODA, Kobe-shi, Hyogo (JP); Minoru NAKAYASU, Kobe-shi, Hyogo (JP); Yoma KANEDA, Kobe-shi, Hyogo (JP); Masamichi SAKAGUCHI, Minato-ku, Tokyo (JP); Takahide YANAGIDA, Kusatsu-shi, Shiga (JP); Yusei MAEDA, Kusatsu-shi, Shiga (JP)

(21) Appl. No.: 17/609,389

(22) PCT Filed: Nov. 6, 2020
(86) PCT No.: PCT/JP2020/041555

§ 371 Date: Nov. 7, 2021

(30) Foreign Application Priority Data
May 1, 2020 (JP) 2020-081506

(51) Int. Cl. H01L 35/32; H01L 35/30; H01L 35/34

(52) U.S. Cl. CPC H01L 35/32; H01L 35/34; H01L 35/30

(57) ABSTRACT

A tubular heat exchanger with a thermoelectric power generation function includes an inner tube 4 in which coolant flows, a thermoelectric power generation module 5 attached to an outer peripheral surface of the inner tube 4, an outer tube 3 attached to an outer peripheral surface of the thermoelectric power generation module 5, and heat collection fins 6 provided on an outer peripheral surface of the outer tube 3. The thermoelectric power generation module 5 generates thermoelectric power using the outer peripheral surface of the inner tube 4 as a low temperature source and an inner peripheral surface of the outer tube 3 as a high temperature source. The inner peripheral surface of the outer tube 3 closely contacts the outer peripheral surface of the thermoelectric power generation module 5.

TECHNICAL FIELD

The present invention relates to a heat exchanger having the function of generating thermoelectric power by means of a temperature difference between an inner tube and an outer tube and a thermoelectric power generation device using the heat exchanger.

BACKGROUND ART

In a current industrial society, mainly in a factory, an electric power plant, a steel plant, an automobile, a building, an illumination, and a ship, an enormous waste heat amount of 60% or more of the total primary energy supply amount has been discharged to global environment. It has been assumed that 75% or more of such waste heat is drainage water or exhaust gas at 250° C. or lower.

Such waste heat is generally transported through an exhaust heat tube. In a tubular heat exchanger configured to exchange heat between, e.g., high-temperature gas flowing in the exhaust heat tube and, e.g., cold water flowing outside the exhaust heat tube, the high-temperature gas can be cooled, but it is difficult to reutilize the exchanged heat for the cold water. This has been an issue for energy saving.

As shown in FIG. 6, Patent Document 1 discloses a tubular heat exchanger with a thermoelectric power generation function, the tubular heat exchanger configured such that a thermoelectric power generation module 110 with a flexible structure is attached to between the outside of a drainage pipe 100 in which, e.g., high-temperature drainage 100A flows and a coolant water pipe 120 in which coolant water 120A flows to generate power by means of a temperature difference between the drainage pipe 100 and the coolant water pipe 120.

In the tubular heat exchanger with the thermoelectric power generation function as disclosed in Patent Document 1, the thermoelectric power generation module 110 is directly cooled with the water, and therefore, a waterproof unit such as attachment of a waterproof sheet needs to be provided outside the thermoelectric power generation module 110. However, the waterproof unit such as the waterproof sheet causes a thermal loss, leading to degradation of the power generation efficiency of the thermoelectric power generation module 110.

### CITATION LIST

Patent Document

PATENT DOCUMENT 1: Japanese Unexamined Patent Publication No. 2009-267316

### SUMMARY OF THE INVENTION

Technical Problem

There is a fin-and-tube heat exchanger configured such that heat collection fins are provided on an outer peripheral surface of a tube and, e.g., heat of high-temperature gas flowing outside the tube is collected by the heat collection fins and is transferred to, e.g., cold water flowing inside the tube. However, the heat exchanger with such a structure can cool the high-temperature gas, but for energy saving, has an issue for reutilization of the exchanged heat for the hot water.

For solving this issue, a thermoelectric power generation module may be used to generate power by means of a temperature difference between cold water and high-temperature gas. However, heat collection fins are directly provided on an outer peripheral surface of a tube in which the cold water flows, and for this reason, it is difficult to attach the thermoelectric power generation module to the outer peripheral surface of the tube.

The present invention has been made in view of the above-described points. A main object of the present invention is to provide a tubular heat exchanger with a thermoelectric power generation function, the tubular heat exchanger being capable of generating thermoelectric power by means of a temperature difference between cold water and high-temperature gas in a fin-and-tube heat exchanger.

### Solution to the Problem

A tubular heat exchanger with a thermoelectric power generation function according to the present invention includes an inner tube in which coolant flows, a thermoelectric power generation module attached to an outer peripheral surface of the inner tube, an outer tube attached to an outer peripheral surface of the thermoelectric power generation module, and a heat collection fin provided on an outer peripheral surface of the outer tube. The thermoelectric power generation module generates thermoelectric power using the outer peripheral surface of the inner tube as a low temperature source and an inner peripheral surface of the outer tube as a high temperature source, and the inner peripheral surface of the outer tube closely contacts the outer peripheral surface of the thermoelectric power generation module.

The method for manufacturing a tubular heat exchanger with a thermoelectric power generation function according to the present invention includes the step of attaching a flexible thermoelectric power generation module to an outer peripheral surface of an inner tube with expansibility, the step of cooling the inner tube, to which the thermoelectric power generation module 5 is attached, to contract the inner tube, the step of inserting the inner tube, to which the thermoelectric power generation module is attached, into an outer tube provided with a heat collection fin on an outer peripheral surface, and the step of heating and expanding the inner tube to cause an inner peripheral surface of the outer tube and an outer peripheral surface of the thermoelectric power generation module to closely contact each other.

### BRIEF DESCRIPTION OF THE DRAWINGS

FIG. 1 is an external perspective view showing the configuration of a heat exchanger in one embodiment of the present invention.

FIG. 2 is a sectional view perpendicular to an axial direction of the heat exchanger in one embodiment of the present invention.

FIG. 3 is a view showing the method for manufacturing the heat exchanger in the present embodiment.

FIG. 4 is a view showing a specific configuration of a thermoelectric power generation module.

FIG. 5 is a sectional view perpendicular to an axial direction of a heat exchanger in a variation of the present invention.

FIG. 6 is an external perspective view of a typical heat exchanger.

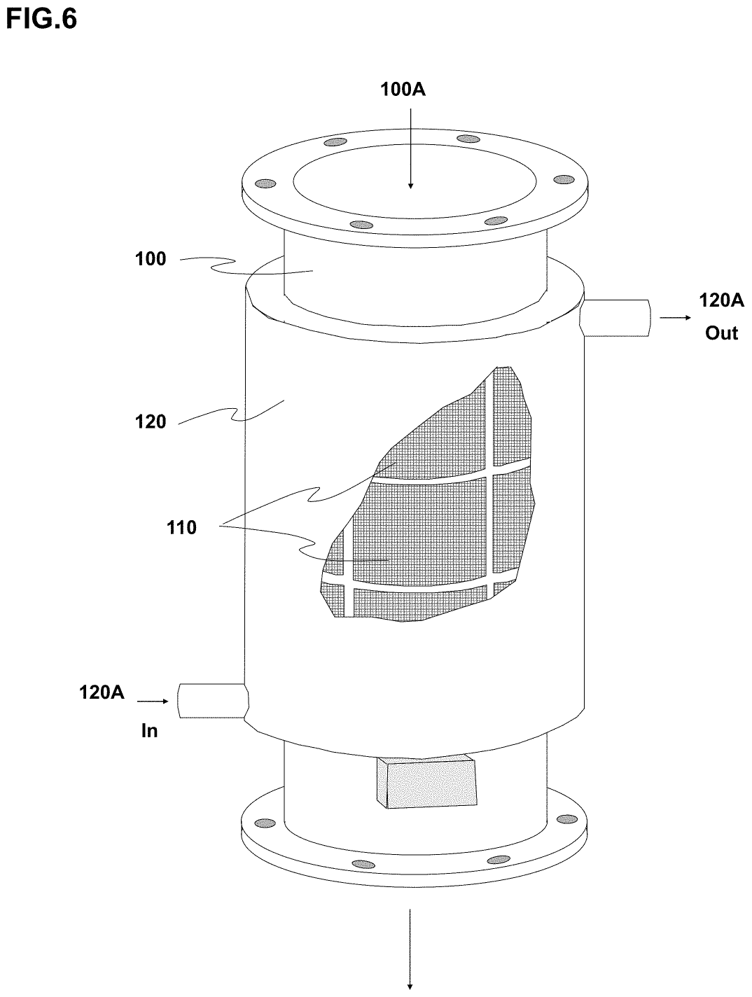

### DESCRIPTION OF EMBODIMENTS

Hereinafter, an embodiment of the present invention will be described in detail based on the drawings. Note that the present invention is not limited to the following embodiment. Moreover, changes can be made as necessary without departing from the scope that advantageous effects of the present invention can be provided.

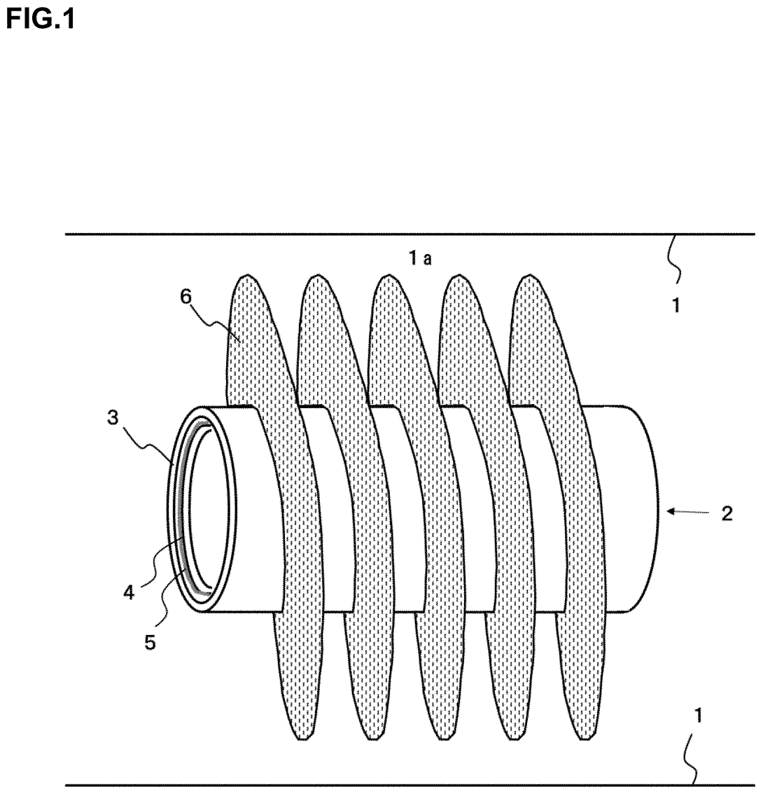

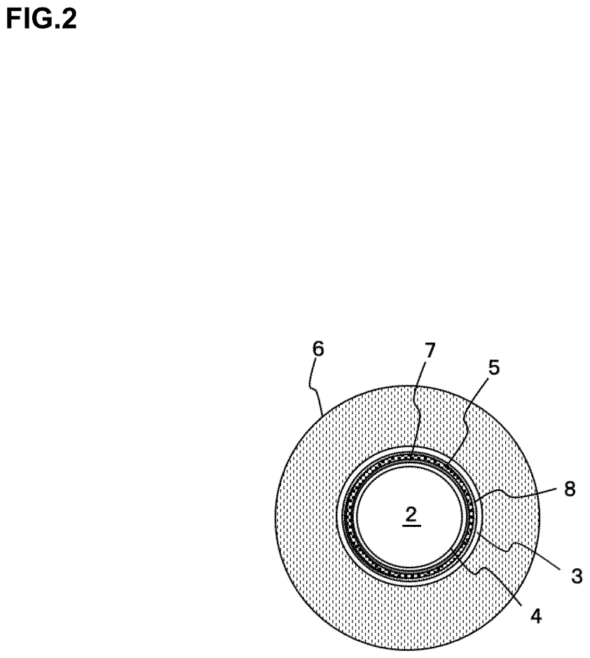

FIGS. 1 and 2 are views schematically showing the configuration of a tubular heat exchanger (hereinafter merely referred to as a “heat exchanger”) with a thermoelectric power generation function in one embodiment of the present invention, FIG. 1 showing an external perspective view and FIG. 2 showing a sectional view perpendicular to an axial direction of the heat exchanger.

As shown in FIGS. 1 and 2, the heat exchanger in the present embodiment includes an inner tube 4 in which a coolant 2 such as coolant water flows, a thermoelectric power generation module 5 attached to an outer peripheral surface of the inner tube 4, an outer tube 3 attached to an outer peripheral surface of the thermoelectric power generation module 5, and heat collection fins 6 provided on an outer peripheral surface of the outer tube 3. An inner peripheral surface of the outer tube 3 closely contacts the outer peripheral surface of the thermoelectric power generation module 5. The heat exchanger described herein is, for example, arranged in a chamber 1 in which exhaust heat gas 1a flows. With this configuration, thermoelectric power generation is performing using the outer peripheral surface of the inner tube 4 as a low temperature source and the inner peripheral surface of the outer tube 3 as a high temperature source in the thermoelectric power generation module 5.

That is, the heat exchanger in the present embodiment is characterized in a configuration in which the thermoelectric power generation module 5 is attached to between double tubes including the inner tube 4 in which the coolant 2 flows and the fin-equipped outer tube 3 in which the high-temperature exhaust heat gas 1a flows. With this configuration, thermoelectric power generation can be performed using the outer peripheral surface of the inner tube 4 as the low temperature source and the inner peripheral surface of the outer tube 3 as the high temperature source in the thermoelectric power generation module 5. Note that, e.g., metal or resin with a low thermal resistance can be used for the inner tube 4 and the outer tube 3.

As shown in FIG. 2, a heat transfer sheet 8 may be provided between the outer peripheral surface of the thermoelectric power generation module 5 and the inner peripheral surface of the outer tube 3. With this configuration, the temperature of the outer peripheral surface of the thermoelectric power generation module 5 can approach the temperature of the inner peripheral surface of the outer tube 3. As a result, a temperature difference in the thermoelectric power generation module 5 can be further increased, and therefore, a power generation efficiency can be further increased.

For the heat transfer sheet 8, a material with a high thermal conductivity, such as a porous metallic material including low-thermal-resistance aluminum, copper, and nickel, a graphite sheet, or metal-plated fabric, can be used. Note that when the temperature of high-temperature gas flowing outside the outer tube 3 changes and the outer tube 3 is expanded/contracted accordingly, there is a probability that adhesion between the outer peripheral surface of the thermoelectric power generation module 5 and the inner peripheral surface of the outer tube 3 is degraded and a thermal loss is caused. For this reason, a material with elasticity or expansibility is preferably used for the heat transfer sheet 8.

As shown in FIG. 2, a thermal conductive sheet 7 may be provided between the outer peripheral surface of the inner tube 4 and an inner peripheral surface of the thermoelectric power generation module 5. With this configuration, the thermal loss relating to attachment of the thermoelectric power generation module 5 between the outer tube 3 and the inner tube 4 can be further reduced. As a result, the temperature difference in the thermoelectric power generation module 5 can be further increased, and the power generation efficiency can be further increased.

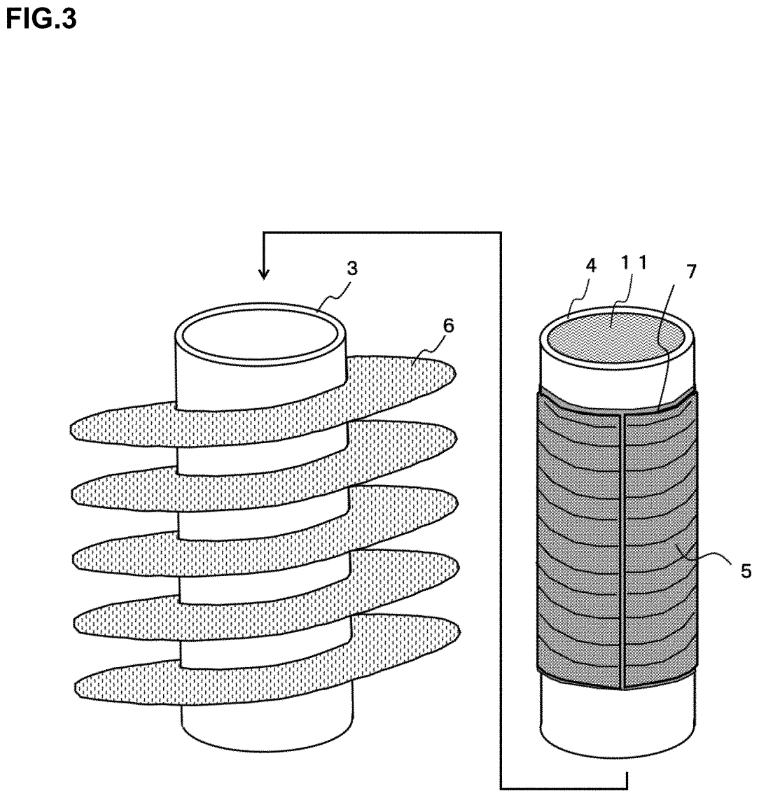

FIG. 3 is a view showing the method for manufacturing the heat exchanger in the present embodiment.

First, the flexible thermoelectric power generation module 5 is, through the thermal conductive sheet 7, attached to the outer peripheral surface of the inner tube 4 with expansibility. Next, the inner tube 4 to which the thermoelectric power generation module 5 is attached is cooled and contracted. Cooling of the inner tube 4 can be, for example, performed in such a manner that liquid nitrogen 11 is charged into the inner tube 4.

Next, the inner tube 4 to which the thermoelectric power generation module 5 is attached is inserted into the outer tube 3 provided with the heat collection fins 6 on the outer peripheral surface. Next, the inner tube 4 is heated and expanded, and in this manner, the outer peripheral surface of the thermoelectric power generation module 5 closely contacts the inner peripheral surface of the outer tube 3. In this manner, the heat exchanger is obtained, which is configured such that the thermoelectric power generation module 5 is attached to between the double tubes including the inner tube 4 and the fin-equipped outer tube 3.

The heat exchanger can be also manufactured by the following method. That is, the flexible thermoelectric power generation module 5 is attached to the outer peripheral surface of the inner tube 4 through the thermal conductive sheet 7 with flexibility. Next, the outer tube 3 is attached in close contact with the outer peripheral surface of the thermoelectric power generation module 5. Next, the heat collection fins 6 are welded to the outer peripheral surface of the outer tube 3. In this manner, the heat exchanger is obtained, which is configured such that the thermoelectric power generation module 5 is attached to between the double tubes including the inner tube 4 and the fin-equipped outer tube 3.

According to the present embodiment, an energy-saving tubular heat exchanger with a thermoelectric power generation function can be achieved, the tubular heat exchanger being capable of generating thermoelectric power by means of a temperature difference between coolant and high-temperature gas in a fin-and-tube heat exchanger.

The thermoelectric power generation module 5 used in the present embodiment has such a structure that two types of thermoelectric elements with different polarities are alternately arranged and electromotive force is generated by a temperature difference between a high-temperature-side electrode and a low-temperature-side electrode.

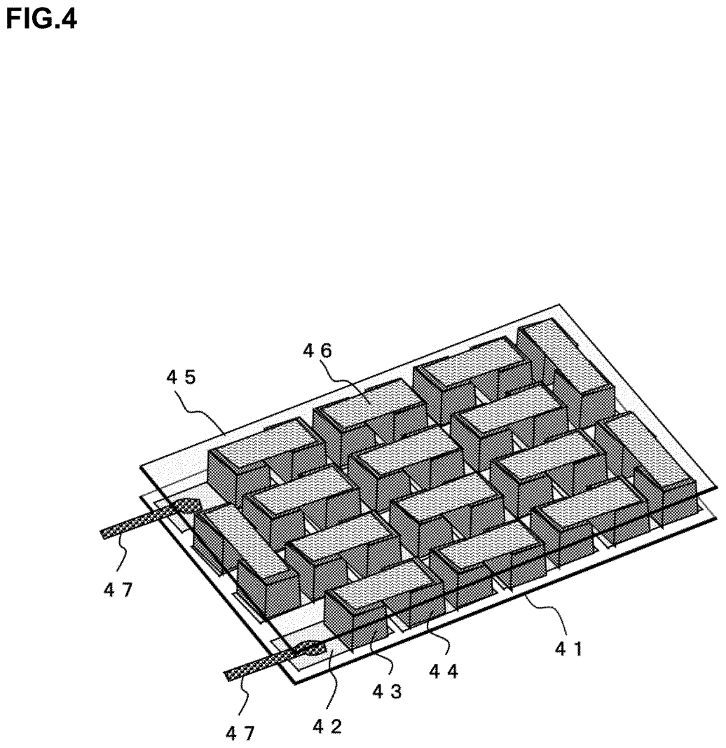

FIG. 4 is a view showing a specific configuration of the thermoelectric power generation module 5.

As shown in FIG. 4, P-type thermoelectric elements 43 and N-type thermoelectric elements 44 are alternately arrayed and mounted on wiring lands 42 formed on a flexible base substrate 41. The P-type thermoelectric element 43 and the N-type thermoelectric element 44 are directly connected to each other through a wiring layer 46 formed on a flexible upper wiring board 45. Generated thermoelectric power is taken out through lead-out electrodes 47.

A specific configuration of the heat exchanger in the present embodiment includes, for example, the inner tube 4 with an outer diameter of 25 mm, the outer tube 3 with an inner diameter of 33 mm, the heat collection fins 6 with a height of 16 mm, and the thermoelectric power generation module 5 with a thickness of 2.5 mm and a planar size of 50×100 mm. In the heat exchanger having such a configuration, an output of about 3.3 W is obtained in a case where an exhaust gas temperature around the heat collection fin 6 is 180° C. and a coolant temperature in the inner tube 4 is 40° C.

The present invention has been described above with reference to the preferred embodiment. However, the present invention is not limited to such description, and needless to say, various modification can be made to the present invention.

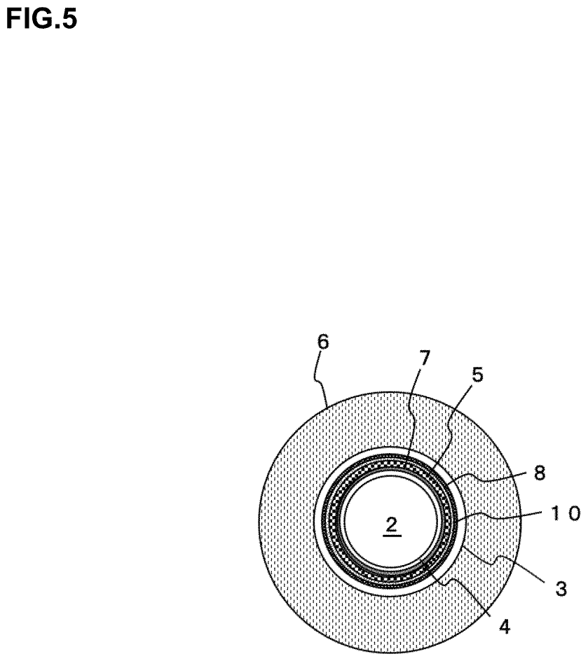

For example, as shown in FIG. 5, a heat collection body 10 may be further provided between the inner peripheral surface of the outer tube 3 and the heat transfer sheet 8. With this configuration, the effect of collecting heat by the heat collection fins 6 can be enhanced, and therefore, the high-temperature-source-side temperature of the thermoelectric power generation module 5 can be further increased. As a result, the temperature difference in the thermoelectric power generation module 5 can be further increased, and therefore, the power generation efficiency can be further increased. As the heat collection body 10, a copper plate with a thickness of 0.2 mm or a carbon sheet with a high thermal conductivity can be used, for example.

Instead of providing the heat transfer sheet 8, a clearance may be provided between the outer peripheral surface of the thermoelectric power generation module 5 and the inner peripheral surface of the outer tube 3, and the inner peripheral surface of the outer tube 3 may be coated with black body radiation paint. With this configuration, heat collected by the inner peripheral surface of the outer tube 3 can be, by infrared radiation, transferred to the outer peripheral surface of the thermoelectric power generation module 5.

The coefficient of thermal expansion of the inner tube 4 may be higher than the coefficient of thermal expansion of the outer tube 3. With this configuration, the inner tube 4 can be further expanded when the outer peripheral surface of the thermoelectric power generation module 5 comes into close contact with the inner peripheral surface of the outer tube 3 by heating and expansion of the inner tube 4. As a result, the adhesion between the outer peripheral surface of the thermoelectric power generation module 5 and the inner peripheral surface of the outer tube 3 can be further enhanced. As the inner tube 4 and the outer tube 3 described above, 18-8 stainless steel with a thermal expansion coefficient of 17.3 (×10⁻⁶/° C.) or 18 chrome stainless steel with a thermal expansion coefficient of 9.0 (×10⁻⁶/° C.) can be used.

Application of the heat exchanger as described in these embodiments to a boiler feedwater preheating economizer can achieve a thermoelectric power generation device configured to generate, using boiler feedwater as a low temperature source and boiler exhaust heat gas as a high temperature source, power in a thermoelectric power generation module of a heat exchanger while preheating the boiler feedwater. Other examples of the exhaust heat gas include exhaust gas from an exhaust gas boiler, a water tube boiler, a once-through boiler, a gas- or oil-fired chiller, an industrial furnace, etc.

### DESCRIPTION OF REFERENCE CHARACTERS

1 Chamber
1a Exhaust Heat Gas
2 Coolant
3 Outer Tube
4 Inner Tube
5 Thermoelectric Power Generation Module
6 Heat Collection Fin
7 Thermal Conductive Sheet
8 Heat Transfer Sheet
10 Heat Collection Body
41 Base Substrate
42 Wiring Land
43 P-Type Thermoelectric Element
44 N-Type Thermoelectric Element
45 Upper Wiring Board
46 Wiring Layer
47 Lead-Out Electrode

1. A fin-and-tube heat exchanger with a thermoelectric power generation function, comprising:
an inner tube in which fluid flows;
a thermoelectric power generation module attached to an outer peripheral surface of the inner tube;
an outer tube attached to an outer peripheral surface of the thermoelectric power generation module; and
a heat collection fin provided on an outer peripheral surface of the outer tube,
wherein the thermoelectric power generation module generates thermoelectric power by means of a temperature difference between the outer peripheral surface of the inner tube and an inner peripheral surface of the outer tube, and
the inner peripheral surface of the outer tube closely contacts the outer peripheral surface of the thermoelectric power generation module.

2. The fin-and-tube heat exchanger with the thermoelectric power generation function according to claim 1, wherein
a heat transfer sheet made of a material having elasticity or expansibility is further provided between the outer peripheral surface of the thermoelectric power generation module and the inner peripheral surface of the outer tube.

3. The fin-and-tube heat exchanger with the thermoelectric power generation function according to claim 2, wherein
the heat transfer sheet is formed of a porous metal film, a graphite sheet, or metal-plated fabric.

4. (canceled)

5. The fin-and-tube heat exchanger with the thermoelectric power generation function according to claim 2, wherein
a heat collection body is further provided between the inner peripheral surface of the outer tube and the heat transfer sheet.

6. The fin-and-tube heat exchanger with the thermoelectric power generation function according to claim 1, wherein
a coefficient of thermal expansion of the inner tube is higher than a coefficient of thermal expansion of the outer tube.

7. (canceled)

8. A method for manufacturing a fin-and-tube heat exchanger with a thermoelectric power generation function, comprising:
a step of attaching a flexible thermoelectric power generation module to an outer peripheral surface of an inner tube with expansibility;
a step of cooling the inner tube, to which the thermoelectric power generation module 5 is attached, to contract the inner tube;
a step of inserting the inner tube, to which the thermoelectric power generation module is attached, into an outer tube provided with a heat collection fin on an outer peripheral surface; and
a step of heating and expanding the inner tube to cause an inner peripheral surface of the outer tube and an outer peripheral surface of the thermoelectric power generation module to closely contact each other.

9. The method for manufacturing the fin-and-tube heat exchanger with the thermoelectric power generation function according to claim 8, wherein
at the step of attaching the thermoelectric power generation module, the thermoelectric power generation module is attached to the outer peripheral surface of the inner tube with the expansibility through a heat transfer sheet with expansibility.

10. A method for manufacturing a fin-and-tube heat exchanger with a thermoelectric power generation function, comprising:
a step of attaching a flexible thermoelectric power generation module to an outer peripheral surface of an inner tube through a heat transfer sheet with flexibility;
a step of attaching an outer tube in close contact with an outer peripheral surface of the thermoelectric power generation module; and
a step of welding a heat collection fin to an outer peripheral surface of the outer tube.

11-13. (canceled)

14. A thermoelectric power generation device for generating power by converting exhaust gas thermal energy supplied from outlet exhaust gas from an exhaust gas boiler, a water tube boiler, or a once-through boiler into the power in a thermoelectric power generation module of a heat exchanger,
the heat exchanger being the fin-and-tube heat exchanger with the thermoelectric power generation function according to claim 1.

15. A thermoelectric power generation device for generating power by converting outlet exhaust gas thermal energy from a gas- or oil-fired refrigerator into the power in a thermoelectric power generation module of a heat exchanger,
the heat exchanger being the fin-and-tube heat exchanger with the thermoelectric power generation function according to claim 1.

16. A thermoelectric power generation device for generating power by converting outlet exhaust gas thermal energy from an industrial furnace into the power in a thermoelectric power generation module of a heat exchanger,
the heat exchanger being the fin-and-tube heat exchanger with the thermoelectric power generation function according to claim 1.
